(19) United States
(12) Patent Application Publication
(10) Pub. No.: US 2010/0003778 A1
(43) Pub. Date: Jan. 7, 2010

(54) METHOD OF MANUFACTURING SEMICONDUCTOR LASER

(75) Inventors: Hitoshi Tada, Tokyo (JP); Tsutomu Yamaguchi, Tokyo (JP); Zempei Kawazu, Tokyo (JP); Yuji Okura, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/274,435

(22) Filed: Nov. 20, 2008

(30) Foreign Application Priority Data
Jul. 7, 2008 (JP) 2008-176771

(51) Int. Cl. H01L 33/00

(52) U.S. Cl. 438/39; 257/E33.006

(57) ABSTRACT

A method of manufacturing a semiconductor laser includes sequentially forming a first conductivity type semiconductor layer, an active layer, and a second conductivity type semiconductor layer on top of one another on a semiconductor substrate; forming a ridge in the second conductivity type semiconductor layer; forming a first insulating film on the second conductivity type semiconductor layer at a first temperature; forming a second insulating film on the first insulating film at a second temperature, lower than the first temperature; and forming an electrode on the second insulating film.

### BACKGROUND OF THE INVENTION

1. Field of the Invention

The present invention relates to a method of manufacturing a semiconductor laser in which an insulating film covers the semiconductor layer having the ridge formed therein, and more particularly to a method of manufacturing such a semiconductor laser having high efficiency and reliability.

2. Background Art

There has been a great need to increase the output and the functionality and reduce the cost of semiconductor lasers for use in optical disc systems. In response to this need, the following method has been used to manufacture a semiconductor laser. First, a first conductivity type semiconductor layer, an active layer, and a second conductivity type semiconductor layer are sequentially formed on top of one another on a semiconductor substrate. Next, a ridge is formed in the second conductivity type semiconductor layer. An insulating film is then formed on the second conductivity type semiconductor layer. Lastly, an electrode is formed on the insulating film. This method requires only one crystal growth step to produce a semiconductor laser having the desired characteristics. (See, e.g., Japanese Laid-Open Patent Publication No. 2001-160650.)

### SUMMARY OF THE INVENTION

Semiconductor layers have different coefficients of thermal expansion than insulating films and electrodes. Therefore, forming an insulating film or electrode on a semiconductor layer causes stress in the layer. Ridge semiconductor lasers are especially susceptible to such stress, since in these lasers the active layer is located near the insulating film. That is, the active layer is distorted due to the stress, resulting in a change in the optical characteristics and causing crystal defects. This has been a factor which has limited the reliability of ridge semiconductor lasers.

Further, in ridge semiconductor lasers, the generated light is confined within the waveguide by utilizing the difference in refractive index between the ridge and the portions of the semiconductor layer on both sides of the ridge. Therefore, the active layer and the insulating film are separated from each other by a very small distance (approximately 0.3 μm) on both sides of the ridge. As a result, light generated in the active layer leaks into the insulating film, and a portion of the leaked light reaches the electrode on the insulating film and is absorbed therein, resulting in reduced efficiency of the semiconductor laser. To avoid this, the insulating film between the semiconductor layer and the electrode may be increased in thickness. However, an increase in the thickness of the insulating film results in an increase in the distortion of the active layer due to the difference in coefficient of thermal expansion between the semiconductor layer and the insulating film.

One way to reduce the stress in the semiconductor layer, or active layer, due to the insulating film thereon is to form the insulating film by plasma CVD, etc. However, this causes plasma damage to the active layer, thereby degrading the reliability of the semiconductor laser.

The present invention has been devised to solve the above problems. It is, therefore, an object of the present invention to provide a method of manufacturing a semiconductor laser having high efficiency and reliability.

According to one aspect of the present invention, a method of manufacturing a semiconductor laser, comprises the steps of: sequentially forming a first conductivity type semiconductor layer, an active layer, and a second conductivity type semiconductor layer on top of one another on a semiconductor substrate: forming a ridge in said second conductivity type semiconductor layer; forming a first insulating film on said second conductivity type semiconductor layer at a first temperature; forming a second insulating film on said first insulating film at a second temperature lower than said first temperature; and forming an electrode on said second insulating film.

Thus, the present invention enables the manufacture of a semiconductor laser having high efficiency and reliability.

Other and further objects, features and advantages of the invention will appear more fully from the following description.

### BRIEF DESCRIPTION OF THE DRAWINGS

FIGS. 1-4 are cross-sectional views illustrating a method of manufacturing a semiconductor laser according to a first embodiment of the present invention.

FIG. 5 is a cross-sectional view of a comparative semiconductor laser.

FIG. 6 is a graph showing the relationships between the thickness of the insulating film and the degradation level and efficiency of the comparative semiconductor laser.

FIG. 7 is a cross-sectional view illustrating a method of manufacturing a semiconductor laser according to a second embodiment of the present invention.

FIG. 8 is a perspective view illustrating a method of manufacturing a semiconductor laser according to a second embodiment of the present invention.

FIG. 9 is a cross-sectional view illustrating a method of manufacturing a semiconductor laser according to a third embodiment of the present invention.

FIG. 10 is a perspective view illustrating a method of manufacturing a semiconductor laser according to a third embodiment of the present invention.

FIG. 11 is a top view illustrating a method of manufacturing a semiconductor laser according to a fourth embodiment of the present invention.

FIG. 12 is a cross-sectional view taken along line A-A′ of FIG. 11.

FIG. 13 is a cross-sectional view taken along line B-B′ of FIG. 11.

### DETAILED DESCRIPTION OF THE PREFERRED EMBODIMENTS

### First Embodiment

There will be described, with reference to accompanying drawings, a method of manufacturing a semiconductor laser according to a first embodiment of the present invention.

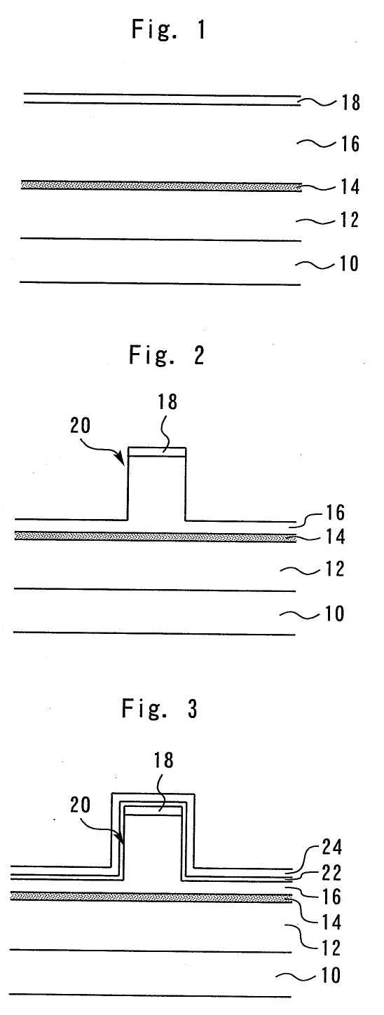

First, an n-type cladding layer 12 (serving as a first conductivity type semiconductor layer), an active layer 14, a p-type cladding layer 16 (serving as a second conductivity type semiconductor layer), and a contact layer 18 are sequentially formed on top of one another on a GaAs substrate 10 (serving as a semiconductor substrate), as shown in FIG. 1. Next, a ridge 20 is formed in the p-type cladding layer 16 by means of photolithography and dry etching, as shown in FIG. 2.

An SiN film 22 (serving as a first insulating film) is then formed on the p-type cladding layer 16 to a thickness of 50 nm by thermal CVD at a temperature of approximately 600° C., as shown in FIG. 3. An SiN film 24 (serving as a second insulating film) is then formed on the SiN film 22 to a thickness of 100 nm by plasma CVD at a temperature of approximately 300° C.

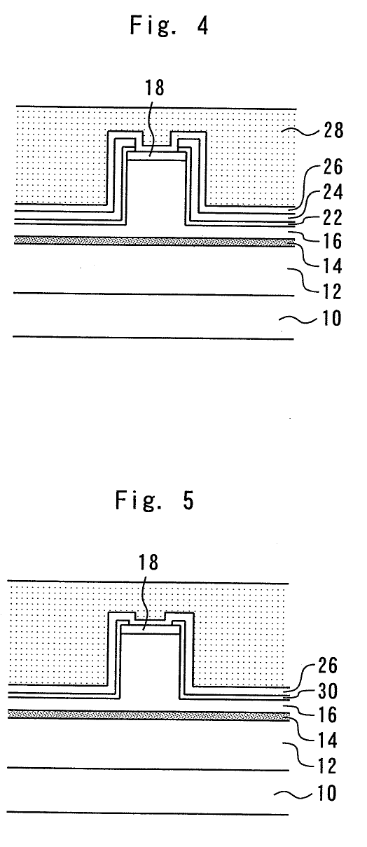

Subsequently, the SiN films 22 and 24 are removed from on top of the ridge 20 to expose the contact layer 18, as shown in FIG. 4. An electrode 26 is then formed over the entire surface of the device structure to a thickness of 400-500 nm, and Au plating 28 is applied over the electrode 26, as shown in FIG. 4. General process steps are then applied to the device structure to complete the manufacture of the semiconductor laser of the present embodiment.

It should be noted that this semiconductor laser has the following dimensions and features: the resonator length is 2.2 mm; the optical waveguide of the ridge 20 is 1.5 μm in width; the SiN films 22 and 24 have a refractive index of 2.0; and the oscillation wavelength is 660 nm.

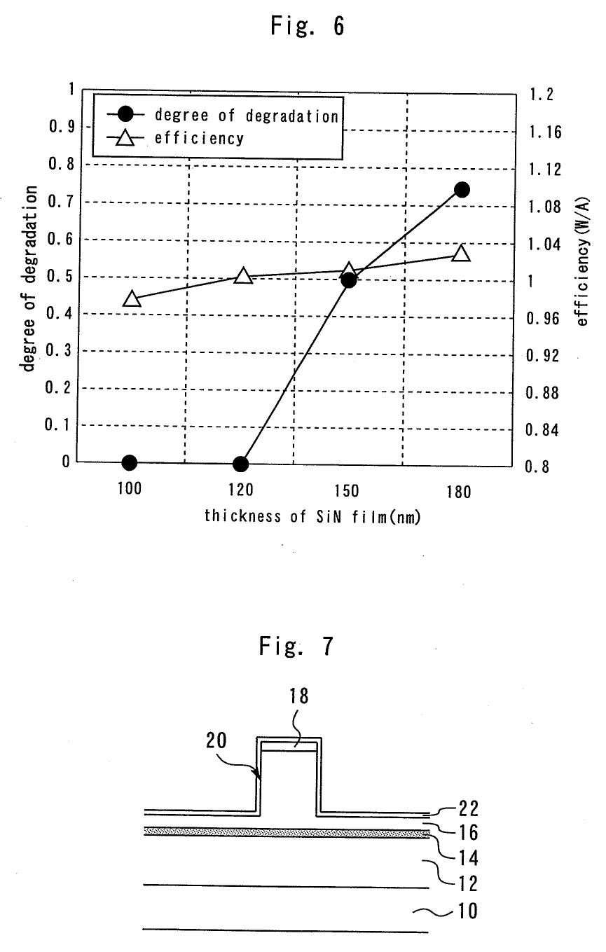

FIG. 5 is a cross-sectional view of a comparative semiconductor laser. This comparative semiconductor laser differs from the semiconductor laser of the present embodiment only in that the SiN films 22 and 24 are replaced by a single SiN film 30 with a thickness of, e.g., 100 nm formed by thermal CVD. FIG. 6 is a graph showing the relationships between the thickness of the insulating film and the degradation level and efficiency of the comparative semiconductor laser. This graph was obtained by applying a 350 mW pulse to the laser at 75° C. As shown in the graph of FIG. 6, the degree of degradation dramatically increased when the thickness of the SiN film 30 was 150 nm or more. The efficiency, on the other hand, increased only gradually with increasing thickness of the SiN film 30. This means that it is difficult to increase the efficiency of the comparative semiconductor laser while retaining its reliability.

On the other hand, the semiconductor laser of the present embodiment includes two stacked insulating films, i.e., the upper SiN film 24 and the lower SiN film 22, as described above. The upper SiN film 24 is formed at lower temperature than the lower SiN film 22. This allows the thickness of the upper SiN film 24 to be increased while limiting the stress in the semiconductor layer (i.e., the p-type cladding layer 16) due to the difference in coefficient of thermal expansion between the semiconductor layer and the overlying SiN films, thereby ensuring the reliability of the semiconductor laser. The increased thickness of the upper SiN film 24 prevents the electrode 26 from absorbing light generated in the active layer 14, resulting in increased efficiency of the semiconductor laser. Further, when the upper SiN film 24 is formed by plasma CVD, the lower SiN film 22 serves to prevent exposure of the semiconductor layer to the plasma, i.e., prevent plasma damage to the semiconductor layer, thereby ensuring the reliability of the semiconductor laser.

According to the present embodiment, the SiN film 22 is formed at a temperature of approximately 600° C. and the SiN film 24 is formed at a temperature of approximately 300° C. However, the optimum film forming temperatures may vary depending on the configuration of the furnace and the film forming conditions. It should be noted that the SiN film 22 must be formed at a temperature of 500° C. or higher and the SiN film 24 must be formed at a temperature of less than 500° C. to achieve the effect described above.

The thermal CVD process can form the SiN film 22 in such a manner that the film fully covers the significantly irregular top surface of the ridge 20. Incidentally, when the ridge 20 is formed, a damaged layer a few tens of nanometers thick is formed on the surface of the p-cladding layer 16, and carrier inactivation occurs. Therefore, the annealing effect of the thermal CVD process may be used to restore the damaged layer and activate the inactivated carriers.

Further, since the SiN film 22 is formed at a high temperature (approximately 600° C.), great stress is set up in the semiconductor layer due to the difference in coefficient of thermal expansion between the SiN film 22 and the semiconductor layer if the SiN film 22 has a large thickness. According to the present embodiment, the SiN film 22 has a thickness of 100 nm or less to reduce the stress in the semiconductor laser due to the thermal expansion coefficient difference. The SiN film 24, on the other hand, has a thickness of 50-200 nm in order to prevent the electrode 26 from absorbing light generated in the active layer 14.

If desired, the SiN film 22 (serving as a first insulating film) may be replaced by a material that can protect the surface of the semiconductor layer. (SiN provides high moisture resistance, as is known in the art.) Further, the SiN film 24 may be replaced by an SiON film or SiO₂film. The SiON film is particularly preferred since it has a tendency to act as a low stress film.

### Second Embodiment

There will be described, with reference to accompanying drawings, a method of manufacturing a semiconductor laser according to a second embodiment of the present invention. It should be noted that components corresponding to those of the first embodiment bear the same reference numerals and will not be further described (unless necessary).

First, an n-type cladding layer 12, an active layer 14, a p-type cladding layer 16, and a contact layer 18 are sequentially formed on top of one another on a GaAs substrate 10, and then a ridge 20 is formed in the p-type cladding layer 16, as in the first embodiment.

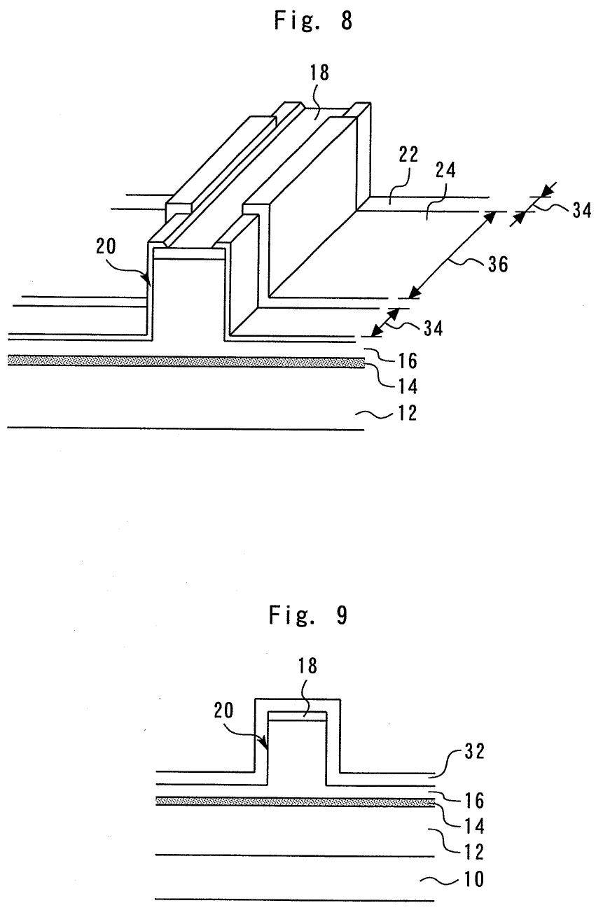

Next, an SiN film 22 is formed over the entire surface of the p-type cladding layer 16, as shown in FIG. 7. An SiN film 24 is then formed on the SiN film 22 in such a manner that the SiN film 24 covers only a central region 36 of the resonator, as shown in FIG. 8. It should be noted that the SiN film 24 is formed at lower temperature than the SiN film 22. Subsequently, the SiN films 22 and 24 are removed from on top of the ridge 20 to expose the contact layer 18, and then an electrode 26 is formed, as in the first embodiment. General process steps are then applied to the device structure to complete the manufacture of the semiconductor laser of the present embodiment.

Thus, according to the present embodiment, the SiN film 24 is not formed on the end regions 34 of the resonator which extend from the respective end faces of the resonator and which tend to undergo distortion, thereby ensuring the reliability of the semiconductor laser. Further, the SiN film 24 formed on the resonator central region 36 prevents the electrode 26 from absorbing light generated in the active layer 14, resulting in increased efficiency of the semiconductor laser.

### Third Embodiment

There will be described, with reference to accompanying drawings, a method of manufacturing a semiconductor laser according to a third embodiment of the present invention. It should be noted that components corresponding to those of the first embodiment bear the same reference numerals and will not be further described (unless necessary).

First, an n-type cladding layer 12, an active layer 14, a p-type cladding layer 16, and a contact layer 18 are sequentially formed on top of one another on a GaAs substrate 10, and then a ridge 20 is formed in the p-type cladding layer 16, as in the first embodiment.

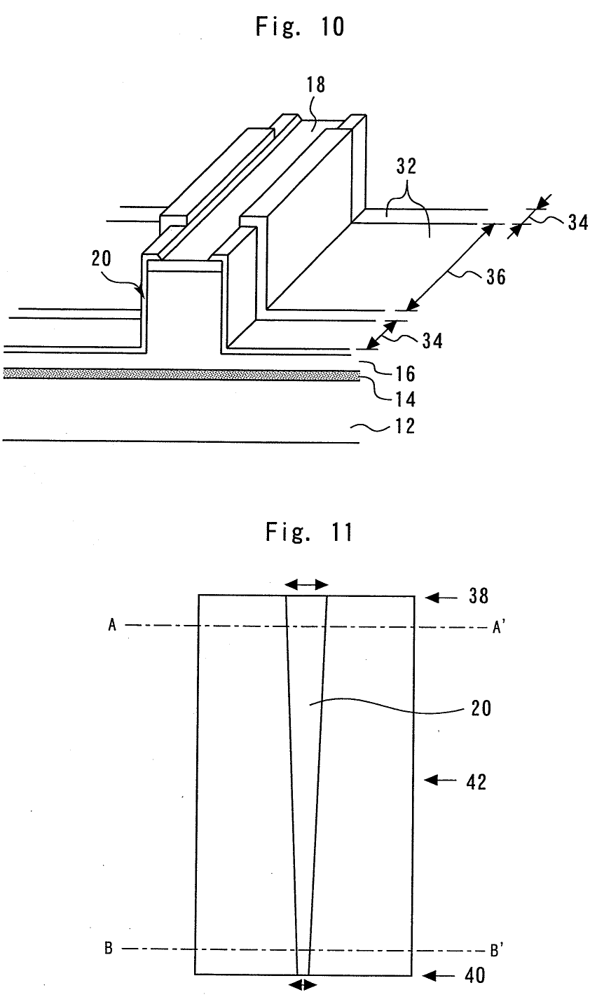

Next, an SiN film 32 (serving as an insulating film) is formed on the p-type cladding layer 16 by thermal CVD at a temperature of approximately 600° C., as shown in FIG. 9.

Etching using a fluorine-containing gas is then performed to thin the SiN film 32 on end regions 34 of the resonator to a thickness of 100 nm or less, as shown in FIG. 10 (the end regions 34 of the resonator extending approximately 20-50 μm from the respective device end faces). It will be noted that since the SiN film 32 is easily etched by fluorine-containing gas, any desired portion of the SiN film 32 can be thinned to a controlled thickness.

Subsequently, the SiN film 32 is removed from on top of the ridge 20 to expose the contact layer 18, and an electrode 26 is formed, as in the first embodiment. General process steps are then applied to the device structure to complete the manufacture of the semiconductor laser of the present embodiment.

Thus, according to the present embodiment, the SiN film 32 has a smaller thickness on the end regions 34 of the resonator, which tend to undergo distortion, than on the central region 36 of the resonator, thereby ensuring the reliability of the semiconductor laser. Further, the SiN film 32 on the central region 36 of the resonator, which has a relatively large thickness, prevents the electrode 26 from absorbing light generated in the active layer 14, resulting in increased efficiency of the semiconductor laser.

### Fourth Embodiment

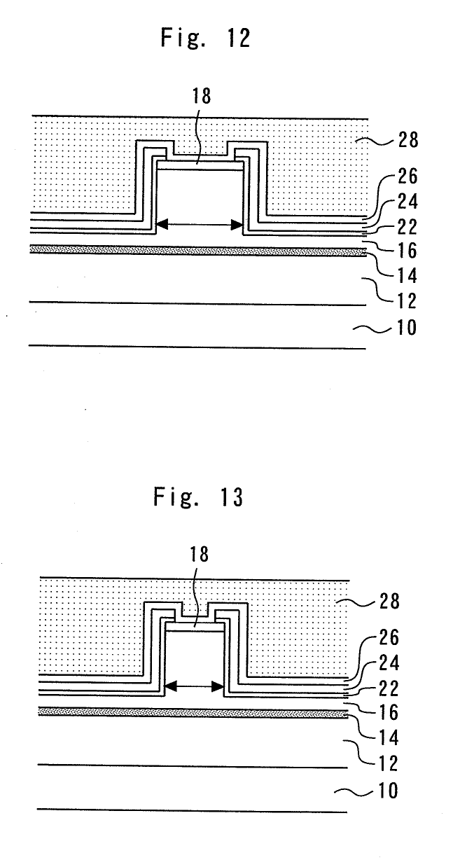

FIG. 11 is a top view illustrating a method of manufacturing a semiconductor laser according to a fourth embodiment of the present invention. FIG. 12 is a cross-sectional view taken along line A-A′ of FIG. 11, and FIG. 13 is a cross-sectional view taken along line B-B′ of FIG. 11.

This semiconductor laser is characterized in that the ridge, 20, is greater in width at the light emitting end face 38 of the laser than at the light reflecting end face 40 or the resonator central portion 42 of the laser (see FIG. 11). According to the present example, the width of the ridge 20 is 2.5 μm at the light emitting end face 38 and 1.5 μm at the light reflecting end face 40. However, the optimum width of the ridge 20 varies depending on the layer stack structure including the active layer 14. Further, the width of the ridge 20 must be such that high-order modes are not present therein. All other components are the same as in the first embodiment.

Thus, since the ridge 20 is greater in width at the light emitting end face 38 than at the other portions, it is possible to reduce the resistance and reduce the operating temperature rise of the end region of the ridge 20 extending from the light emitting end face 38. Further, an increase in the width of the ridge 20 means that both sides of the ridge 20, at which stress is most concentrated, are spaced an increased distance from the center of the light distribution, resulting in increased reliability of the semiconductor laser, as compared to the first embodiment. It should be noted that the present embodiment may be combined with the second or third embodiment.

Although the present invention has been described with reference to the semiconductor lasers of the first to fourth embodiments for use with optical discs, it is to be understood that the invention may be applied to lasers for other applications made of a different material such as GaN—, InP—, or AlGaAs-based material, with the same advantages.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2008-176771, filed on Jul. 7, 2008 including specification, claims, drawings and summary, on which the Convention priority of the present application is based, are incorporated herein by reference in its entirety.

1. A method of manufacturing a semiconductor laser, comprising:
sequentially forming a first conductivity type semiconductor layer, an active layer, and a second conductivity type semiconductor layer on top of one another on a semiconductor substrate:
forming a ridge in said second conductivity type semiconductor layer;
forming a first insulating film on said second conductivity type semiconductor layer at a first temperature;
forming a second insulating film on said first insulating film at a second temperatures lower than the first temperature; and
forming an electrode on said second insulating film.

2. The method as claimed in claim 1, including forming said second insulating film on said first insulating film such that said second insulating film covers only a central region of a resonator of said semiconductor laser.

3. The method as claimed in claim 1, wherein the first temperature is at least 500° C., and the second temperature is lower than 500° C.

4. The method as claimed in claim 1, including forming said first insulating film by thermal chemical vapor deposition (CVD).

5. The method as claimed in claim 1, wherein said first insulating film has a thickness not exceeding 100 nm, and said second insulating film has a thickness in a range from 50 nm to 200 nm.

6. The method as claimed in claim 1, wherein said first insulating film is SiN, and said second insulating film is one of SiON and SiO₂.

7. A method of manufacturing a semiconductor laser, comprising:
sequentially forming a first conductivity type semiconductor layer, an active layer, and a second conductivity type semiconductor layer on top of one another on a semiconductor substrate;
forming a ridge in said second conductivity type semiconductor layer;
forming an insulating film on said second conductivity type semiconductor layer;
etching said insulating film on an end region of a resonator of said semiconductor laser so that said insulating film has a smaller thickness on the end region than on a central region of the resonator, the end region extending from an end face of the resonator; and
forming an electrode on said insulating film.

8. The method as claimed in claim 1, wherein said ridge has a larger width at a light emitting face of said semiconductor laser than at a light reflecting end face or a central resonator portion of said semiconductor laser.
